(19) United States
(12) Patent Application Publication
(10) Pub. No.: US 2016/0037619 A1
(43) Pub. Date: Feb. 4, 2016

(54) CARRIER SUBSTRATE AND METHOD OF MANUFACTURING PRINTED CIRCUIT BOARD USING THE SAME

(71) Applicant: SAMSUNG ELECTRO-MECHANICS CO., LTD., Suwon-si (KR)

(72) Inventors: Yong Ho BAEK, Suwon-Si (KR); Young Gwan KO, Suwon-Si (KR); Jae Hoon CHOI, Suwon-Si (KR); Il Jong SEO, Suwon-Si (KR); Sung Uk LEE, Suwon-Si (KR); Eung Suek LEE, Suwon-Si (KR)

(21) Appl. No.: 14/734,933

(22) Filed: Jun. 9, 2015

(30) Foreign Application Priority Data
Jul. 29, 2014 (KR) 10-2014-0096673

(51) Int. Cl. H05K 1/02; H05K 3/10; H05K 3/06; H05K 3/40

(52) U.S. Cl. CPC H05K 1/02; H05K 3/4007; H05K 3/10; H05K 3/06

(57) ABSTRACT

There are provided a carrier substrate including: a first metal layer; a barrier layer formed on one surface of the first carrier metal layer; and a second metal layer formed on one surface of the barrier layer, and a method of manufacturing a printed circuit board using the same.

### CROSS-REFERENCE TO RELATED APPLICATION

This application claims the benefit of Korean Patent Application No. 10-2014-0096673, filed on Jul. 29, 2014, entitled “Carrier Substrate and Method of Manufacturing Printed Circuit Board Using The Same” which is hereby incorporated by reference in its entirety into this application.

### BACKGROUND

The present disclosure relates to a carrier substrate and a method of manufacturing a printed circuit board using the same.

In general, a printed circuit board is formed by forming wirings on one surface or both surfaces of a board made of various thermosetting synthetic resins using a copper wire, fixedly disposing integrated circuits (ICs) or electronic components on the board, implementing the electrical wirings between the ICs or the electronic components, and then coating the electrical wirings using an insulator.

In accordance with the recent development of electronic industry, the demand for multi-functional and slim and light electronic components has rapidly increased. Therefore, a printed circuit board having the electronic components mounted thereon has also been demanded to have a high density wiring and a thin thickness.

In particular, in order to implement the thin thickness of the printed circuit board, a core substrate is not used, such that an overall thickness of the printed circuit board may be decreased, and therefore, a coreless substrate capable of reducing a signal treatment time has received attention.

In the coreless substrate, the core substrate is not used, such that a carrier member performing a support body function in a manufacturing process is required.

### RELATED ART DOCUMENT

### Patent Document

(Patent Document 1) Korean Patent Laid-Open Publication No. 2009-0029508

### SUMMARY

An aspect of the present disclosure may provide a carrier substrate capable of providing a bump pad having a fine pitch, and a method of manufacturing a printed circuit board using the carrier substrate.

Another aspect of the present disclosure may provide a carrier substrate capable of reducing cost and time, and a method of manufacturing a printed circuit board using the carrier substrate.

According to an aspect of the present disclosure, a carrier substrate may include: a first metal layer; a barrier layer formed on one surface of the first carrier metal layer; and a second metal layer formed on one surface of the barrier layer.

The barrier layer may be made of a material which does not react with an etching solution reacting with the first metal layer and the second metal layer.

According to another aspect of the present disclosure, a method of manufacturing a printed circuit board may include: preparing a carrier substrate including a first metal layer, a second metal layer, and a barrier layer formed between the first metal layer and the second metal layer; forming circuit patterns on one surface of the second metal layer; forming an insulation layer on one surface of the second metal layer to bury the circuit patterns; removing the first metal layer; patterning the barrier layer; and forming a bump pad by removing the second metal layer exposed to the outside through the barrier layer.

The barrier layer may be made of a material different from those of the first metal layer and the second metal layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified diagram illustrating a carrier substrate according to an exemplary embodiment of the present disclosure.

FIGS. 2 through 11 are exemplified diagrams illustrating a method of manufacturing a printed circuit board according to exemplary embodiments of the present disclosure.

### DESCRIPTION OF EMBODIMENTS

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

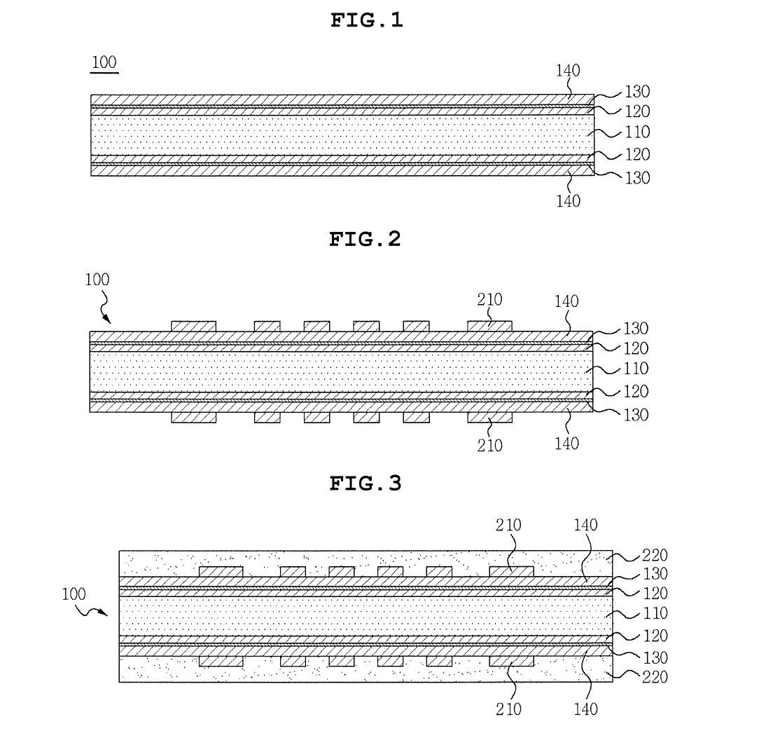

FIG. 1 is an exemplified diagram illustrating a carrier substrate according to an exemplary embodiment of the present disclosure.

Referring to FIG. 1, the carrier substrate 100 may include a carrier core 110, a first metal layer 120, a barrier layer 130, and a second metal layer 140.

The carrier core 110 according to an exemplary embodiment of the present disclosure is made of a resin insulation material. For example, the carrier core 110 may be made of a thermosetting resin such as an epoxy resin or a thermoplastic resin such as polyimide. Otherwise, the carrier core 110 may be made of prepreg impregnated with a reinforcing agent such as glass fiber or inorganic filler in the thermosetting resin or the thermoplastic resin. Otherwise, the carrier core 110 may be made of a photo-curable resin.

The first metal layer 120 according to the exemplary embodiment of the present disclosure is formed on both surfaces of the carrier core 110. Although a structure in which the first metal layers 120 are formed on both surfaces of the carrier core 110 is shown in FIG. 1, the first metal layer 120 is not necessarily formed on both surfaces of the carrier core 110. That is, the first metal layer 120 may be formed on only one surface of the carrier core 110.

The barrier layer 130 according to the exemplary embodiment of the present disclosure is formed on one surface of the first metal layer 120. When the first metal layer 120 is removed, the barrier layer 130 according to the exemplary embodiment of the present disclosure serves to protect the second metal layer 140 from an etching solution. In addition, the barrier layer 130 serves as a resist for patterning the second metal layer 140.

The second metal layer 140 according to the exemplary embodiment of the present disclosure is formed on one surface of the barrier layer 130. According to the exemplary embodiment of the present disclosure, the second metal layer 140 may be patterned to be used as circuit patterns (not shown).

According to the exemplary embodiment of the present disclosure, the first metal layer 120 and the second metal layer 140 are made of a conductive metal. However, the barrier layer 130 is made of a material different from those of the first metal layer 120 and the second metal layer 140. That is, the barrier layer 130 is made of a material which does not react with the etching solution reacting with the first metal layer 120 and the second metal layer 140. The reason is because the second metal layer 140 needs to be protected from the etching solution, when the first metal layer 120 is etched. In addition, the reason is because the barrier layer needs to serve as an etching resist, when the second metal layer 140 is patterned.

Further, the second metal layer 140 of the exemplary embodiment of the present disclosure is formed of a metal which does not react with the etching solution reacting with the barrier layer 130. The reason is because it is to prevent the second metal layer 140 from being etched when the barrier layer 130 is patterned to be the etching resist by using the etching solution.

For example, the first metal layer 120 and the second metal layer 140 are made of copper. Here, the barrier layer 130 may be made of a metal material such as nickel (Ni), titanium (Ti). Otherwise, the barrier layer 130 may be made of a photosensitive polymer material such as PET, a dry film.

In the exemplary embodiment of the present disclosure, it is shown as an example that the first metal layer 120 and the second metal layer 140 are made of copper. However, the first metal layer 120 and the second metal layer 140 are not necessarily made of the same metal as each other.

In the exemplary embodiment of the present disclosure, it is shown that the carrier substrate 100 includes the carrier core 110 made of an insulation material. However, the carrier substrate 100 is not limited thereto in view of a structure. That is, if the carrier substrate 100 includes a structure having the first metal layer 120, the second metal layer 140, the barrier layer 130 interposed between the first metal layer 120 and the second metal layer 140, the carrier core 110 may be omitted, or may be made of other materials, or may be formed in different structures.

FIGS. 2 through 11 are exemplified diagrams illustrating a method of manufacturing a printed circuit board according to exemplary embodiments of the present disclosure.

Referring to FIG. 2, first circuit patterns 210 are formed on the carrier substrate 100.

According to the exemplary embodiment of the present disclosure, the carrier substrate 100 has a structure in which the first metal layer 120, the barrier layer 130, and the second metal layer 140 are sequentially stacked on both surfaces of the carrier core 110.

The carrier core 110 according to an exemplary embodiment of the present disclosure is made of a resin insulation material. For example, the carrier core 110 is made of a thermosetting resin such as an epoxy resin, a thermoplastic resin such as polyimide, a photo-curable resin, or a prepreg.

The first metal layer 120, the barrier layer 130, and the second metal layer 140 according to the exemplary embodiment of the present disclosure are made of a conductive metal. Here, the barrier layer 130 is made of a material which does not react with the etching solution reacting with the first metal layer 120 and the second metal layer 140. For example, the barrier layer 130 may be made of a metal material such as nickel (Ni), titanium (Ti). Otherwise, the barrier layer 130 may be made of a photosensitive polymer material such as PET, a dry film.

Details of the carrier substrate 100 according to the exemplary embodiment of the present disclosure are appreciated with reference to FIG. 1.

According to the exemplary embodiment of the present disclosure, the first circuit patterns 210 are formed on both surfaces of the carrier substrate 100. That is, the first circuit patterns 210 are formed on an upper part of the second metal layer 140. The first circuit patterns 210 according to the exemplary embodiment of the present disclosure are formed by a method of forming the circuit patterns known in a circuit board field, such as tenting, SAP, and MSAP processes. In addition, the first circuit patterns 210 according to the exemplary embodiment of the present disclosure is made of a conductive material generally used in the circuit printed board. For example, the first circuit patterns 210 are made of copper.

The manufacturing method according to the exemplary embodiment of the present disclosure is described on the basis of an upper part of the carrier substrate 100 in order to assist understanding of explanation. That is, the description is provided on the basis of the manufacturing process performed on the upper part of the carrier substrate 100. In addition, although the description is omitted, the same process is performed in a lower part of the carrier substrate 100. Further, even though it is shown as an example that the same manufacturing process is performed on both surfaces of the carrier substrate 100 in the exemplary embodiment of the present disclosure, the manufacturing process may be performed on only one surface of the carrier substrate 100 according to selection of a person skilled in the art.

Referring to FIG. 3, the first insulation layer 220 is formed.

According to the exemplary embodiment of the present disclosure, the first insulation layer 220 is formed on the upper part of the carrier substrate 100 to bury the first circuit patterns 210.

The first insulation layer 220 according to the exemplary embodiment of the present disclosure may be formed on the upper part of the carrier substrate 100, as a film form, by stacking and pressurizing methods. Otherwise, the first insulation layer 220 may be formed on the upper part of the carrier substrate 100 by applying a material in a liquid phase for forming the insulation layer.

The first insulation layer 220 according to the exemplary embodiment of the present disclosure is made of a complex polymer resin generally used as an interlayer insulation material. For example, the first insulation layer 220 is made of a prepreg, an Ajinomoto build up film (ABF), and an epoxy based resin such as FR-4, bismaleimide triazine (BT).

According to the exemplary embodiment of the present disclosure, the first circuit patterns 210 are buried in the first insulation layer 220 by using the carrier substrate 100. Therefore, even though the first circuit patterns 210 have a fine pitch, the first circuit patterns may be insulated from neighboring patterns due to the first insulation layer 220.

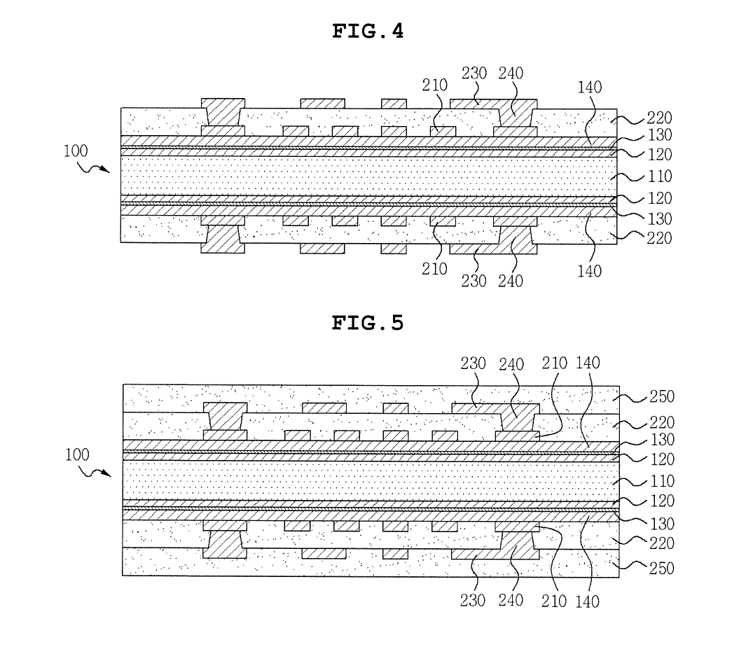

Referring to FIG. 4, the second circuit patterns 230 and a first via 240 are formed.

According to the exemplary embodiment of the present disclosure, the second circuit patterns 230 are formed on the upper part of the first insulation layer 220 In addition, the first via 240 is formed in the first insulation layer 220 to electrically connect the first circuit patterns 210 and the second circuit patterns 230 to each other.

The second circuit patterns 230 and the first via 240 according to the exemplary embodiment of the present disclosure are formed by a method of forming the circuit patterns and the via known in the circuit board field. For example, the second circuit patterns 230 and the first via 240 are formed by one method of tenting, SAP, and MSAP processes.

In addition, the second circuit patterns 230 and the first via 240 according to the exemplary embodiment of the present disclosure are made of a conductive material generally used in the circuit printed board. For example, the second circuit patterns 230 and the first via 240 are made of copper.

Referring to FIG. 5, the second insulation layer 250 is formed.

According to the exemplary embodiment of the present disclosure, the second insulation layer 250 is formed on the upper part of the first insulation layer 220 to bury the second circuit patterns 230.

The second insulation layer 250 according to the exemplary embodiment of the present disclosure may be formed on the upper part of the first insulation layer 220, as a film form, by stacking and pressurizing methods. Otherwise, the second insulation layer 250 may be formed on the upper part of the second insulation layer 220 by applying a material in a liquid phase.

The second insulation layer 250 according to an exemplary embodiment of the present disclosure is made of a complex polymer resin generally used as an interlayer insulation material. For example, the second insulation layer 2 is made of a prepreg, an Ajinomoto build up film (ABF), and an epoxy based resin such as FR-4, bismaleimide triazine (BT).

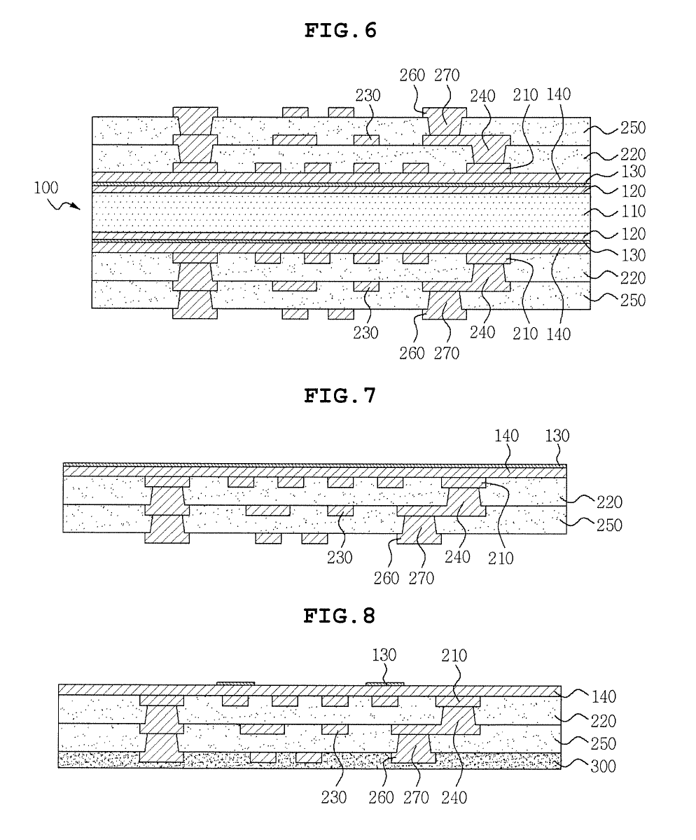

Referring to FIG. 6, the third circuit patterns 260 and the second via 270 are formed.

According to the exemplary embodiment of the present disclosure, the third circuit patterns 260 are formed on the upper part of the second insulation layer 250. In addition, the second via 270 is formed in the second insulation layer 250 to electrically connect the second circuit patterns 230 and the third circuit patterns 260 to each other.

The third circuit patterns 260 and the second via 270 according to the exemplary embodiment of the present disclosure are formed by a method of forming the circuit patterns and the via known in the circuit board field. For example, the third circuit patterns 260 and the second via 270 are formed by one method of tenting, SAP, and MSAP processes.

In addition, the third circuit patterns 260 and the second via 270 according to the exemplary embodiment of the present disclosure are made of a conductive material generally used in the circuit printed board. For example, the third circuit patterns 260 and the second via 270 are made of copper.

Referring to FIG. 7, the carrier substrate 100 in FIG. 6 is removed.

According to the exemplary embodiment of the present disclosure, after the carrier core 110 in FIG. 6 and the first metal layer 120 in FIG. 6 are separated from each other, the first metal layer 120 in FIG. 6 is etched. The first metal layer 120 in FIG. 6 is removed by using the etching solution, and the barrier layer 130 protects the second metal layer 140 from the etching solution.

Referring to FIG. 8, the barrier layer 130 is patterned, and the protective layer 300 is formed.

According to the exemplary embodiment of the present disclosure, the barrier layer 130 is patterned to be used as the etching resist of the second metal layer 140. Here, the barrier layer 130 is patterned so that a portion of the second metal layer 140 to be etched is exposed to the outside.

According to the exemplary embodiment of the present disclosure, the barrier layer 130 is patterned by a method of patterning a metal known in the printed circuit board. For example, the etching resist (not shown) having an opening part is formed in an upper part of the barrier layer 130. In addition, the portion exposed to the outside by the etching resist (not shown) is etched by using the etching solution reacting with the barrier layer 130. Here, the etching solution to be used is an etching solution which does not react with the second metal layer 140. Then, by removing the etching resist (not shown), the barrier layer 130 which is patterned as shown in FIG. 8 is formed.

Otherwise, when the barrier layer 130 is made of a photosensitive polymer material, the barrier layer may be patterned by exposure and development processes.

In addition, according to the exemplary embodiment of the present disclosure, the protective layer 300 is formed. When the second metal layer 140 is etched, the protective layer 300 is formed to protect the third circuit patterns 260 from the etching solution. The protective layer according to the exemplary embodiment of the present disclosure is not limited in view of a kind as long as a material forming the protective layer 300 is an insulation material capable of protecting the third circuit patterns 260 from the etching solution.

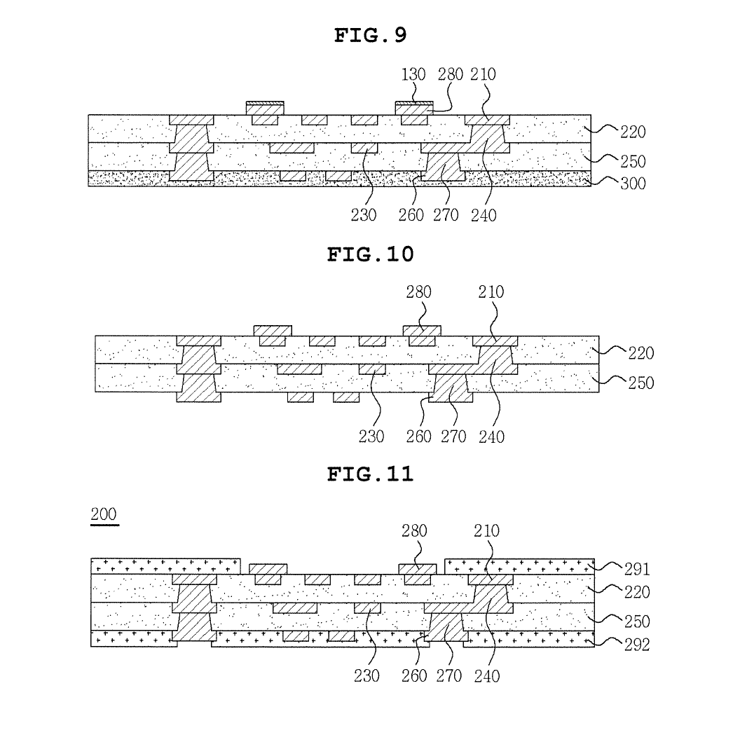

Referring to FIG. 9, the bump pad 280 is formed.

According to the exemplary embodiment of the present disclosure, the second metal layer 140 in FIG. 8, on which the patterned barrier layer 130 is formed, is etched by using the etching solution. Here, the etching solution to be used reacts with the second metal layer 140, but does not react with the barrier layer 130. Therefore, a portion in which the barrier layer 130 is formed in the second metal layer 140 in FIG. 8 is protected from the etching solution, and a portion exposed to the outside is etched. As described above, the second metal layer 140 in FIG. 8 is patterned to form the bump pad 280.

According to the exemplary embodiment of the present disclosure, the barrier layer 130 of the carrier substrate becomes the etching resist, and the second metal layer 140 in FIG. 8 becomes the bump pad 280, such that a process of forming the etching resist and a plating process which are additionally performed in the related art may be omitted. Therefore, it is possible to reduce time and cost.

In addition, according to the exemplary embodiment of the present disclosure, since the barrier layer 130 used as the etching resist has a thin thickness, it is possible to pattern the second metal layer 140 in FIG. 8 in precise and fine size, the bump pad 280 having a fine pitch may be provided.

Referring to FIG. 10, the barrier layer 130 in FIG. 9 and the protective layer 300 in FIG. 9 are removed.

In the exemplary embodiment of the present disclosure, it is shown as an example that the barrier layer 130 in FIG. 9 is removed. However, the present disclosure is not limited thereto. That is, the barrier layer 130 in FIG. 9 may be maintained on the bump pad 280 as it is to thereby become a portion of the bump pad 280.

Referring to FIG. 11, a first solder resist layer 291 and a second solder resist layer 292 are formed.

According to the exemplary embodiment of the present disclosure, at the time of soldering connecting external components such as an electronic device, a substrate, and the like, to the printed circuit board 200, the first solder resist layer 291 and the second solder resist layer 292 protect the circuit patterns from solders. In addition, the first solder resist layer 291 and the second solder resist layer 292 prevent the circuit patterns from being oxidized. The first solder resist layer 291 and the second solder resist layer 292 are made of a heat resistant covering material.

According to the exemplary embodiment of the present disclosure, the first solder resist layer 291 is formed on the upper part of the first insulation layer 220 to cover the first circuit patterns 210. That is, the first solder resist layer 291 is formed so as to cover an upper surface of the first circuit patterns 210. Here, the first solder resist layer 291 is patterned so that the bump pad 280 connected to the external components (not shown) is exposed to the outside.

In addition, according to the exemplary embodiment of the present disclosure, the second solder resist layer 292 is formed on a lower part of the second insulation layer 250 to cover the third circuit patterns 260. Here, the second solder resist layer 292 is patterned so that a portion of the third circuit patterns 260 connected to the external components (not shown) is exposed to the outside.

Although it is not in FIG. 11, surface treatment layers (not shown) are formed on surfaces of the bump pad 280 and the third circuit patterns 260 exposed to the outside through the first solder resist layer 291 and the second solder resist layer 292.

Although it is illustrated that the bump pad 280 is formed on an outermost layer in the exemplary embodiments of the present, the layer formed on the outermost layer is not necessarily the bump pad 280. For example, it is possible to form the circuit patterns (not shown) having the fine pitch on the outermost layer of the printed circuit board 200, instead of the bump pad 280.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A carrier substrate comprising:
a first metal layer;
a barrier layer formed on one surface of the first carrier metal layer; and
a second metal layer formed on one surface of the barrier layer.

2. The carrier substrate of claim 1, further comprising:
a carrier core, and
the first metal layer is formed on one surface or both surfaces of the carrier core.

3. The carrier substrate of claim 1, wherein the barrier layer is made of a material different from those of the first metal layer and the second metal layer.

4. The carrier substrate of claim 1, wherein the barrier layer is made of a material which does not react with an etching solution reacting with the first metal layer and the second metal layer.

5. A method of manufacturing a printed circuit board comprising:
preparing a carrier substrate including a first metal layer, a second metal layer, and a barrier layer formed between the first metal layer and the second metal layer;
forming circuit patterns on one surface of the second metal layer;
forming an insulation layer on one surface of the second metal layer to bury the circuit patterns;
removing the first metal layer;
patterning the barrier layer; and
forming a bump pad by removing the second metal layer exposed to the outside through the barrier layer.

6. The method of claim 5, wherein in the preparing of the carrier substrate, the carrier substrate further includes a carrier core, and the first metal layer is formed on one surface or both surfaces of the carrier core.

7. The method of claim 5, wherein in the preparing of the carrier substrate, the barrier layer is made of a material different from those of the first metal layer and the second metal layer.

8. The method of claim 5, wherein in the preparing of the carrier substrate, the barrier layer is made of a material which does not react with an etching solution reacting with the first metal layer and the second metal layer.

9. The method of claim 5, wherein in the removing of the first metal layer, the first metal layer is removed by an etching solution which does not react with the barrier layer.

10. The method of claim 5, wherein in the patterning of the barrier layer, the barrier layer is patterned so as to cover one surface of a portion of the second metal layer to be the bump pad.

11. The method of claim 5, wherein in the forming of the bump pad, the second metal layer exposed to the outside through the barrier layer is removed by an etching solution, and the etching solution of the second metal layer does not react with the barrier layer.

12. The method of claim 5, wherein in the forming of the bump pad, the bump pad is adhered to one surface of the circuit patterns.

13. The method of claim 5, further comprising, after the forming of the bump pad, removing the barrier layer.
